(19) United States
(12) Patent Application Publication
(10) Pub. No.: US 2003/0157795 A1
(43) Pub. Date: Aug. 21, 2003

(54) Self-aligned patterning in dual damascene process

(75) Inventors: Chia-Chi Chung, Hsin-Chu (TW); Chen-Chen Calvin Hsueh, Taipei (TW)

Correspondence Address: Finnegan, Henderson, Farabow,, Garrett & Dunner, L.L.P., 1300 I Street, N.W., Washington, DC, 20005-3315, US

(73) Assignee: Macronix International Co. Ltd.

(21) Appl. No.: 10/076,630

(22) Filed: Feb. 19, 2002

(51) Int. Cl. H01L 21/4763; H01L 21/311

(52) U.S. Cl. 438/633; 438/645; 438/626; 438/631

(57) ABSTRACT

A semiconductor manufacturing process that includes providing an insulating material, providing a first photoresist over the insulating material, defining and patterning the first photoresist, anisotropically etching the insulating material to form at least one groove in the insulating material, removing the first photoresist, providing a second photoresist over the insulating material, defining and patterning the second photoresist to form a plurality of tops and sidewalls, depositing a layer of carbon-fluoride material over the tops and sidewalls of the defined and patterned second photoresist, and anisotropically etching the insulating layer to form at least one opening, wherein the at least one opening is aligned with the at least one groove.

### FIELD OF THE INVENTION

This invention relates in general to a semiconductor manufacturing process and, more particularly, to a method for preventing misalignment of a photoresist during a dual damascene manufacturing process.

### BACKGROUND OF THE INVENTION

In a semiconductor manufacturing process, one or more metal layers are formed after active devices have been formed to serve as interconnects. The plurality of metal layers are separated from each other by an insulating layer. The metal layers are connected to each other and other devices by vias, or through holes filled with a metallic material in the insulating layer. Damascene is an interconnect fabrication process that provides a plurality of horizontal grooves in an insulating layer and fills the grooves with metal to form conductive lines. Dual damascene is a multi-level interconnect process that, in addition to forming conductive lines, also forms conductive vias. There are generally two known dual damascene processes. In the first process, an insulating layer is coated with a first photoresist. A first mask with patterns of the conductive lines is used to define and pattern the first photoresist. After the first photoresist is developed, the defined and patterned first photoresist and insulating layer are etched anisotropically, and horizontal grooves for the conductive lines are formed in the upper portion of the insulating layer. The first photoresist is then removed.

The insulating layer is coated with a second photoresist. A second mask with patterns of the vias is used to define and pattern the second photoresist. Ideally, the second mask should be accurately aligned with the grooves already formed in the upper portion of the insulating layer because the subsequently formed vias must be electrically connected to the conductive lines. After the second photoresist is developed, the defined and patterned second photoresist and insulating layer are anisotropically etched. Vertical openings for the vias are etched through the insulating material. The grooves and via openings are then filled with metal, such as copper. The resulting surface is then planarized using known chemical-mechanical polish (CMP). The dual damascene may be repeated to form additional interconnect.

In the second dual damascene process, a first mask with patterns of vias is first provided over a first photoresist to define and pattern the first photoresist. After the first photoresist is developed, the defined and patterned first photoresist and insulating layer are etched anisotropically, and vertical openings for the vias are formed in the upper portion of the insulating layer. The first photoresist is then removed. The insulating layer is coated with a second photoresist. A second mask with patterns of the conductive lines is used to define and pattern the second photoresist. After the second photoresist is developed, the defined and patterned second photoresist and insulating layer are anisotropically etched. Horizontal grooves for the conductive lines are formed in the upper half of the insulating layer, and via openings are etched through the insulating material. The grooves and via openings are then filled with metal, such as copper. The resulting surface is then planarized using CMP.

Because two photoresist processes are used to form the openings and grooves, misalignment of the second photoresist creates defect in the manufacturing process, especially for the dual damascene process where the horizontal grooves are formed before the via openings. The difficulty lies in having to accurately align the via openings in the grooves already formed in the insulating layer. Any misalignment will create metal misalignment between the vias and conductive lines, and adversely affect the functionality of the vias.

It is accordingly a primary object of the invention to provide a method to improve metal alignment in dual damascene processes.

This is achieved by forming a thin film comprising a carbon-fluoride compound on the second photoresist using a low-temperature chemical-vapor deposition (CVD) process.

### SUMMARY OF THE INVENTION

In accordance with the invention, there is provided a method for improving alignment in a dual damascene process that includes providing an insulating layer, providing a photoresist over the insulating layer, defining and patterning the photoresist, wherein the defined and patterned photoresist includes tops and sidewalls, depositing a layer of carbon-fluoride material over the tops and sidewalls of the photoresist, anisotropically etching the insulating layer to create at least one opening, and filling the at least one opening with metal to form at least one

In one aspect, the carbon-fluoride material is deposited at a temperature lower than 100° C.

In another aspect, the ratio of carbon to fluorine in the carbon-fluoride material is at least 0.25.

Also in accordance with the present invention, there is provided a semiconductor manufacturing process that includes providing an insulating material, providing a first photoresist over the insulating material, defining and patterning the first photoresist, anisotropically etching the insulating material to form at least one groove in the insulating material, removing the first photoresist, providing a second photoresist over the insulating material, defining and patterning the second photoresist to form a plurality of tops and sidewalls, depositing a layer of carbon-fluoride material over the tops and sidewalls of the defined and patterned second photoresist, and anisotropically etching the insulating layer to form at least one opening, wherein the at least one opening is aligned with the at least one groove.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate one embodiment of the invention and together with the description, serve to explain the principles of the invention.

### BRIEF DESCRIPTION OF THE DRAWINGS

FIGS. 1-6 are cross-sectional views of the semiconductor manufacturing steps consistent with the method of the present invention.

### DESCRIPTION OF THE EMBODIMENTS

Reference will now be made in detail to the present embodiment of the invention, an example of which is illustrated in the accompanying drawings. Wherever possible, the same reference numbers will be used throughout the drawings to refer to the same or like parts.

The method of the present invention improves metal alignment in dual damascene processes by providing a thin film comprising a carbon-fluoride compound on a photoresist using a low-temperature chemical-vapor deposition (CVD) process to increase alignment margin between the grooves for the conductive lines and the openings for the vias.

FIGS. 1-6 are cross-sectional views of the semiconductor manufacturing steps consistent with the method of the present invention. Referring to FIG. 1, a semiconductor structure (not numbered) includes a first layer 10, a second layer 12 and an insulating layer 14. The first layer 10 may be a metal layer, such as a layer of copper, or any material used in the semiconductor manufacturing process. The second layer 12 may be a dielectric layer, such as silicon nitride. The insulating layer 14 may be any insulating material, such as an oxide material. The first layer 10, second layer 12 and insulating layer 14 may be formed using conventional semiconductor manufacturing process. The insulating layer 14 is then coated with a first photoresist 16. A first mask (not shown) with patterns of conductive lines is used to define and pattern the first photoresist 16.

Referring to FIG. 2, after the first photoresist 16 is developed, the defined and patterned first photoresist 16 and insulating layer 14 are etched anisotropically. At least one horizontal groove 18 for the conductive lines is formed in the upper portion of the insulating layer 14. Although only one groove is shown in FIG. 2, one skilled in the art would understand that more than one groove might be formed using this process. The first photoresist 16 is then removed.

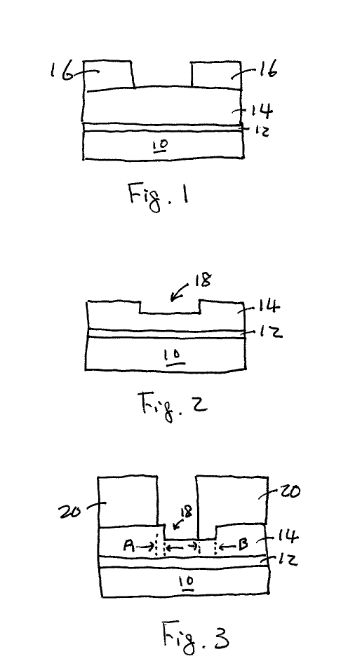

Referring to FIG. 3, the insulating layer 14 is coated with a second photoresist 20. A second mask (not shown) with patterns of vias is used to define and pattern the second photoresist 20. As shown in FIG. 3, the second mask is not accurately aligned with the groove already formed in the upper portion of the insulating layer 14. As a result, the defined and patterned second photoresist 20 is not accurately aligned with the groove 18. Specifically, the defined and patterned second photoresist 20 is misaligned with the groove 18 by a distance of “A” on one side and “B” on the other.

Referring to FIG. 4, a thin film 22 is formed over the misaligned second photoresist 20, covering the tops and sidewalls of the second photoresist 20. The thin film 22 is comprised of a carbon-fluoride compound C_{X}H_{y}Fₓ. The carbon-fluoride film 22 is formed over the second photoresist 20 with a low-temperature CVD process. In particular, this process is performed in high-density plasma-etching equipment. The temperature of the CVD process is less than 100° C. The reactive gases used may be one of C₄F₈, CH₂F₂, C₃F₈, C₄F₆, C₅F₈, etc, together with nonreactive gases carbon monoxide (CO) and argon (Ar). In a preferred embodiment, the ratio of carbon to fluorine should be greater than or equal to 0.25.

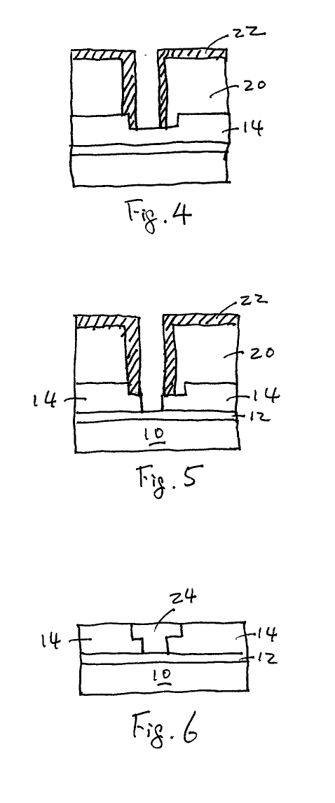

Referring to FIG. 5, after the thin film 22 is formed over the second photoresist 20, the semiconductor structure is anisotropically etched. Vertical openings for the vias are etched through the insulating material 14. Referring to FIG. 6, the thin film 22 and second photoresist 20 are removed. The grooves and via openings are filled with metal 24, such as copper, connecting the conductive lines with the vias. The resulting surface is then planarized.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for improving alignment in a dual damascene process, comprising:
providing an insulating layer;
providing a photoresist over the insulating layer;
defining and patterning the photoresist, wherein the defined and patterned photoresist includes tops and sidewalls;
depositing a layer of carbon-fluoride material over the tops and sidewalls of the photoresist;
anisotropically etching the insulating layer to create at least one opening; and
filling the at least one opening with metal to form at least one via.

2. The method as claimed in claim 1, wherein the carbon-fluoride material is deposited at a temperature lower than 100° C.

3. The method as claimed in claim 1, wherein the ratio of carbon to fluorine in the carbon-fluoride material is at least 0.25.

4. The method as claimed in claim 1, wherein the step of depositing a layer of carbon-fluoride material is a chemical-vapor deposition process.

5. The method as claimed in claim 1, wherein the insulating layer includes at least one groove, and wherein the defined and patterned photoresist is misaligned with the groove before the step of depositing a layer of carbon-fluoride material.

6. A semiconductor manufacturing process, comprising:
providing an insulating material;
providing a first photoresist over the insulating material;
defining and patterning the first photoresist;
anisotropically etching the insulating material to form at least one groove in the insulating material;
removing the first photoresist;
providing a second photoresist over the insulating material;
defining and patterning the second photoresist to form a plurality of tops and sidewalls;
depositing a layer of carbon-fluoride material over the tops and sidewalls of the defined and patterned second photoresist; and
anisotropically etching the insulating material to form at least one opening, wherein the at least one opening is aligned with the at least one groove.

7. The method as claimed in claim 6, wherein the carbon-fluoride material is deposited at a temperature lower than 100° C.

8. The method as claimed in claim 6, wherein the ratio of carbon to fluorine in the carbon-fluoride material is at least 0.25.

9. The method as claimed in claim 6, wherein the step of depositing a layer of carbon-fluoride material is a chemical-vapor deposition process.

10. The method as claimed in claim 6, wherein the defined and patterned second photoresist is misaligned with the at least one groove in the insulating layer.

11. The method as claimed in claim 6, further comprising a step of filling the at least one opening and the at least one groove with metal.
